(19) United States
(12) Patent Application Publication
(10) Pub. No.: US 2004/0082309 A1
(43) Pub. Date: Apr. 29, 2004

(54) Printer

(76) Inventor: Freddie W. Smith, Boise, ID (US)

Correspondence Address: HEWLETT-PACKARD COMPANY, Intellectual Property Administration, P.O. Box 272400, Fort Collins, CO, 85527-2400, US

(21) Appl. No.: 10/282,084

(22) Filed: Oct. 29, 2002

(51) Int. Cl. H04B 1/04; H01Q 11/12; H04B 1/06; H05K 11/00

(52) U.S. Cl. 455/344; 455/117

(57) ABSTRACT

A printer is provided and is adapted to print jobs from a network. The printer includes a Faraday shield for enclosing a plurality of electrical components and parts in the printer. The shield includes a component for enabling wireless communication with the network. The component includes an antenna.

### BACKGROUND OF THE INVENTION

The field of the invention generally relates to wireless communication between one or more computers in a network to a printer.

At almost every corporate environment, network systems are used to improve business or increase productivity in some way. Network systems may generally be divided into two types: wired networks and wireless networks. In a wired network such as a (wired) local area network (LAN) for example, a group of computers are linked or connected (wired) together to allow each computer to exchange email, transfer files, share software applications, do video conferencing and use the same printers. In a typical wired network, several printers are connected to the network via a serial data cable. Each computer in the network is assigned a dedicated printer for printing print jobs. The print job may be submitted via the network by Unix, mainframe or Windows based applications.

Similar to the wired network, wireless networks also function to allow a group of computers to exchange email, transfer files, etc. In wireless networks, however, the computers in the network are linked, i.e., communicate with each other by way of a radio frequency carrier to share information. Wireless networks may be server-based such as a wireless LAN (WLAN) or a peer-to-peer network. Wireless networks may be implemented as an extension to, or as an alternative to a wired network. WLANs, for example, are typically found within a small client node-dense locale (a campus or office building) or anywhere a traditional network cannot be deployed for logistic reasons. Communication is based on IEEE 802.1 1b, the predominant technology standard used to achieve mobility in wireless environments. However, other protocols are also used to achieve wireless communication such as Bluetooth and IrDA.

While wired networks such as LANs have been the mainstream technology for at least fifteen years, WLANs are increasing in popularity because they have several benefits. WLANs offer a user mobility in a coverage area, are simple to set up, and are scalable. WLANs also provide security features such as encryption, frequency hopping and firewalls. WLANs, however, have their drawbacks. The hardware for WLANs are costly. WLANs may be vulnerable to interference and need to be security enabled for clients. In addition, wireless communication between the computers and the peripheral devices in the network are often difficult.

However, where Radio links have been utilized as a replacement for cables, the additional hardware required to achieve communication is both cumbersome and expensive. Moreover, installation and configuration are often complicated. In an effort to overcome these shortcomings, radio printed circuit boards (or separately combined electronic cards components) have been developed that offer a simple way to achieve wireless communication. The signals are typically transmitted via an antenna that is attached to the exterior of the peripheral device. This exterior antenna, however, increases the likelihood that it will be damaged by falling objects because they are exposed. Furthermore, the exterior antenna is unattractive and may hinder a manufacturer's ability to sell the peripheral device.

At present, there is no simple, attractive, and “universal” design for a printer that enables it to achieve wireless communication with a computer in any network.

### SUMMARY OF THE INVENTION

In an exemplary embodiment of the invention, a printer is provided that is adapted to print jobs from a network, the printer comprising: a Faraday shield for covering a plurality of electrical parts in the printer, the shield including a component for enabling wireless communication with the network.

In another exemplary embodiment of the invention, a printer is provided that is adapted to print jobs from a network via a wireless connection, the printer comprising: a controlling component for controlling the operation of the printer; the controlling component including a plurality of electrical parts; and a shield for enclosing the controlling component, the shield is constructed to (1) reduce electromagnetic radiation generated by the plurality of electrical parts from escaping the printer and (2) reducing stray electromagnetic radiation from affecting the plurality of electrical parts of the controlling component, the shield including a component for enabling wireless communication with the network.

In yet another exemplary embodiment of the invention, a printer is provided that is adapted to achieve wireless communication with a network, the printer comprising: a Faraday shield for enclosing a plurality of electrical parts in a printer, the shield including an antenna coupled to at least one of the plurality of electrical parts for communicating with the network.

### BRIEF DESCRIPTION OF THE DRAWINGS

The accompanying drawings, which are incorporated herein and constitute a part of the specification, illustrate a presently preferred embodiment of the invention, and together with the general description given above and the detailed description of the preferred embodiment given below, serve to explain the principals of the invention.

FIG. 1 is a block diagram illustrating a system of components including a printer incorporating the preferred embodiment of the present invention.

FIG. 2 is an enlarged view of the printer shown in FIG. 1 illustrating internal components.

FIG. 3 is a perspective view of the Faraday shield inside the printer shown in FIG. 1 incorporating a slot antenna in accordance with the preferred embodiment of the present invention.

FIG. 4 is an inside view of the Faraday shield shown in FIG. 3 illustrating the connection between the slot antenna and the circuit board.

FIG. 5A is a perspective view of a portion of the Faraday shield incorporating an antenna in accordance with an alternate embodiment of the present invention.

FIG. 5B is a cross sectional view of the shield and the antenna taken along lines 5B-5B in FIG. 5A.

FIG. 6A is a perspective of a portion of the Faraday shield incorporating an antenna in accordance with another alternate embodiment of the present invention.

FIG. 6B is a cross sectional view of shield and the antenna taken along 6B-6B in FIG. 6A.

### DESCRIPTION OF THE PREFERRED EMBODIMENT

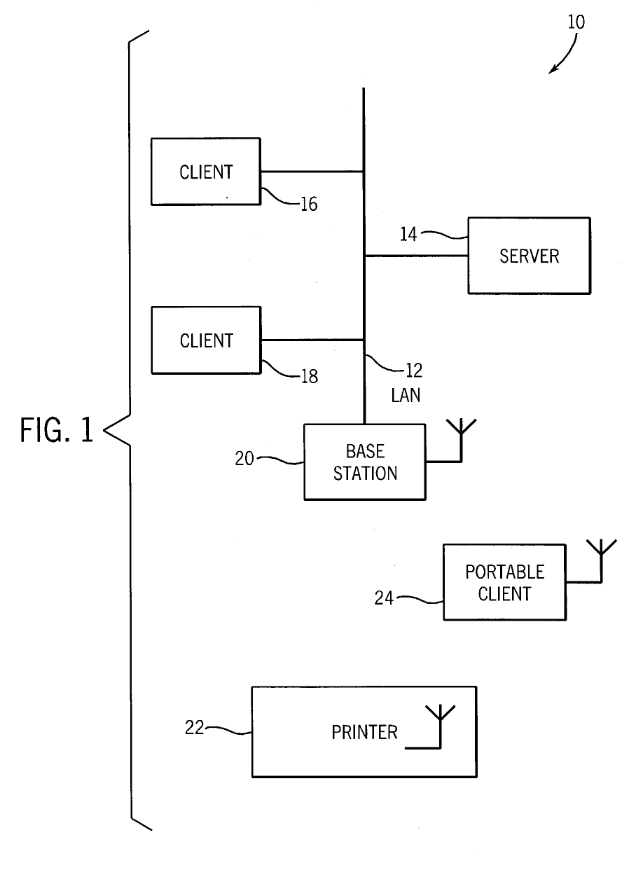

Referring to FIG. 1, there is shown a computer system 10 in which a (wired) server-based LAN 12 is connected to a server 14 for storing application software and files and routing shared information to several clients 16, 18. Server 14 includes the customary components of a computer including a CPU, a network or communications interface, RAM or ROM or other memory, as well as suitable storage devices such as disk or CD-ROM drives. Server 14 also includes a suitable network card or other communication device (not shown) that is used as an interface between server 14 and LAN 12. The network card communicates with the operating system of server 14 by way of a TCP/IP stack (not shown). A server based LAN is preferred, but other LANs may be employed for achieving communication between the clients, such as a peer-to-peer network. The most common software choices today seeking a server based LAN is some variant of Unix, Microsoft Windows 2000 or NT or XP, or Novell Netware. Microsoft Windows 2000 or Windows XP however are the preferred operating systems for server 14 and clients 16, 18.

Each client site 16, 18 may be implemented in a preferred embodiment, by a personal computer and a monitor. Alternatively, each client may be implemented by a cellular telephone, PDA, or other appliances equipped with browsers and networking. Clients 16, 18 also include a suitable network card or interface (not shown) along with a TCP/IP protocol stack (not shown) for communicating with server 14 and with other network devices over LAN 12. Network 12 can be an Ethernet or Token Ring network, but it can also be implemented by a telephone line network or a wireless network, using the IEEE 802.1 1b or Bluetooth or other wireless network protocol.

More generally, a client can be a PC, telephone, PDA, appliance, etc. equipped with an industry-standard (HTTP, FTP, WAP, HTML, XML, WML, cHTML, HDML, etc.) browser having wired (Ethernet, Token Ring, etc.) or wireless (cellular, Bluetooth, IEEE 802.1 1b, etc.) access via networking (TCP/IP, Novell, NetBUI, Appletalk, etc.) to nearby and/or remote peripherals, devices, appliances, etc. The preferred embodiment will focus upon a device that utilizes the TCP/IP protocol (transfer control protocol/Internet protocol) for communication between peers or between clients or between clients and servers, each client device having an internal TCP/IP protocol stack, where the lower portion of the protocol stack could be Ethernet, Token Ring, Bluetooth, IEEE 802. 1 1b, or whatever protocol is needed to facilitate the transfer of IP packets over a local area network.

For purposes of communication between clients, it is presumed that some mechanism is provided for assigning IP addresses to each client and to the server. For example, server 14 could function as a DHCP server, assigning IP addresses to each of the clients, printers, scanners, etc. whenever they become active and join the local network 12. Alternatively, each device might have a permanently assigned IP address. Or, in a peer-to-peer network, some other arrangement may be used whereby the peers may assign themselves addresses and identify themselves, as in a Bluetooth wireless network.

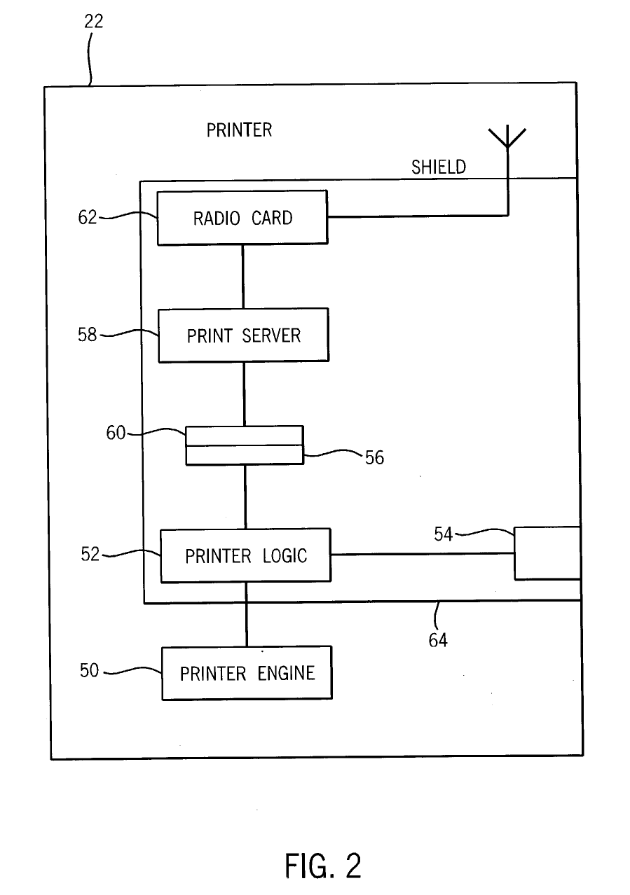

Returning now to FIG. 1, system 10 also includes an access point or base station 20 and a mobile or wireless printer 22. The main function of base station 20 is to form a bridge between wired LANs and wireless LANs and devices. Base station 20 is not mobile. It forms part of the wired network infrastructure. In the preferred embodiment shown, printer 22 is linked via a radio frequency carrier directly to base station 20. However it is possible to also employ intervening base stations to communicate with a wired network via base station 20 over longer distances. It is also possible to have the printer 22 communicate directly and wirelessly with wireless clients such as portable computers, PDAs, etc. without the communication passing through any base station as in Apple Airport systems. Details of internal components of the printer are discussed below with respect to FIG. 2.

System 10 also includes a portable client 24. Client 24 is typically a laptop that includes the customary components of a computer including a screen, a CPU, RAM or ROM or other memory, as well as suitable storage devices such as disk or CD-ROM drives. Client 24 also includes suitable components including a network card for communicating (wireless) with server 14 and LAN 12 via base station 20. The network card communicates with the operating system of server 14 by way of TCP/IP stack (not shown).

Base station 20 and portable client 24 each include an external antenna for wireless communication with other wireless networks, devices, etc., as shown in FIG. 1. Printer 22 also includes an antenna, but it is internal as described in more detail below.

Referring to FIG. 2, there is shown certain internal components of printer 22 in accordance with the preferred embodiment. Printer 22 includes printer engine 50 and printer logic 52. Printer logic 52 typically includes components on one or more printed circuit boards (part of printer 22). However, in alternative embodiments, these components may not require circuit boards. Printer logic 52 generally makes up the component for controlling the operation of printer 22. Printer engine 50 is typically a laser print engine that prints images on paper using a toner under the control of printer logic 52, although other types of printer engines (ink jet, etc.) may be used. Printer logic 52 includes the customary electrical parts including programs and logic as described below (not shown) to convert Postscript and other types of image descriptions into bit images. Printer engine 50 includes the electrical and mechanical parts required to print the bit images on paper.

In a typical printer, there is one or more serial ports and a parallel port and they appear on the housing of the printer to enable a user to connect the printer to a computer or network print server directly using a printer cable. In the preferred embodiment shown in FIG. 2, printer 22 includes two printer connector ports (25 PIN). External printer port 54 is a first parallel port that may be used in the traditional way to enable a user to connect printer 22 to a computer, or through an external print server, to a network directly, if wireless connection is not desirable or is not possible. A printer port 56 comprises a second internal parallel connector port, and it is used to couple printer logic 52 to printer server 58 by way of mating connector 60 and cable coupled to printer server 58. Printer server 58 is a conventional component and may be purchased off the shelf. It may connect to an external Ethernet connector 54, which can be wired directly to a network without the need for an external print server, if wireless connection is not desirable or not possible. Printer server 58 includes a protocol stack capable of supporting, for example, Appletalk, TCP/IP, NetBUI, and possibly other network protocols. Printer server 58 may take several forms. It is preferably a network card adapted to be inserted into a slot on the printed circuit board. While a parallel port connection between print server 58 and printer logic 52 is shown, both of these elements could communicated serially or over a shared system bus, and both could occupy a shared circuit board.

Printer 22 also includes radio card 62 that may be inserted into a slot on the circuit board. Radio card 62 includes the customary components for wireless connection to enable transmission and reception, such as a transceiver (for modulation and carrier transmission and reception). Typically, it could be a PCMCIA card. Instead of a card, equivalent logic could be mounted up on a circuit board which could be the print server circuit board or the printer logic circuit board. Radio card 62 is preferably designed to support the IEEE 802.1 1b wireless protocol standard. However, other protocols may be supported such as Bluetooth. Radio card 62 is coupled to the print server 58.

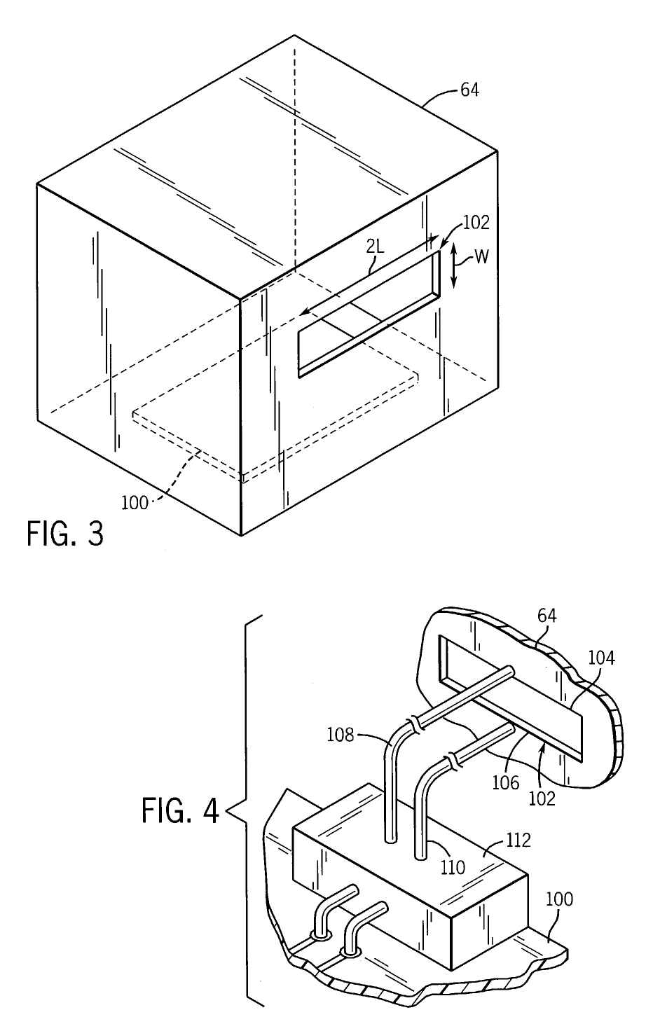

Printer 22 includes a Faraday cage or shield 64 enclosing the circuit board and other electronic components (e.g., printer logic 52, port 56, connector 60, print server 58, radio card 62 and a portion of port 54) in printer 22. In a typical arrangement, the purpose of the Faraday shield is two fold. First, Faraday shield 64 is used to trap or reduce RF noise generated by the electronic parts of the components (printer logic 52 and peripheral cards including printer 58 and radio card 62) on the circuit board, such as high powered ASICs, CPU, memory, interfaces, network cards, etc., and the traces or connection lines which connect the electrical parts of the components together. At the same time, shield 64 is used to reduce the tendency of stray radio frequency signals in the vicinity of the printer from affecting (reduce vulnerability) those same electronic parts on the printer circuit board. In FIG. 2, shield 64 includes a component for enabling wireless communication with network 12 of system 10. Shield 64, as well as the component for enabling wireless communication (shown in FIGS. 1 and 2 as a three prong fork) are shown in more detail in FIGS. 3 and 4 and are described in more detail below.

In FIG. 3, Faraday shield 64 is shown in representative form. Shield 64 is preferably a six-sided box that encloses circuit board 100 (dotted lines). Shield 64 (enclosure) includes a plurality of small holes. These holes are used for connection wires, such as serial or parallel cables or power lines needed to power the circuit board, and for ventilation (for permitting air flow for cooling the electronic components on board 100). As described above, shield 64 also includes a component for enabling wireless communication with network 12. The component is preferably slot 102, an integral part of shield 64. Slot 102 acts as an antenna by transmitting and receiving signals to and from network 12 via base station 20. In operation, a voltage is created in Faraday shield 64 across slot 102. If transmission is desired, a voltage representing information is generated across slot 102 to induce an electromagnetic field across slot 102 that radiates from shield 64. If reception is desired, Faraday shield 64 receives a signal from network 12 when a voltage is generated in shield 64 across slot 102.

The dimensions (width “W” and length “2L”) of slot 64 along with the thickness of the metal dictate the frequency of transmission and reception. In general, the frequency of the antenna is primarily determined by the length of the slot (2L in FIG. 3), where 2L is chosen to be approximately λ/2. λ is the wavelength associated with the chosen frequency. The parameter W also affects the tuned frequency and is typically adjusted to achieve the desired bandwidth of the antenna. To maintain a specified center frequency the length (2L) is shortened as W is increased. In the preferred embodiment, frequency of transmission and/or reception is 2.45 GHz. (However, other frequencies are acceptable.) At 2.45 GHz, λ is approximately 12.25 cm. Therefore, 2L should be approximately 6.125 cm. The appropriate parameters (2L and W) can be determined through either analysis or experimentation to satisfy particular communications requirements.

Slot 64 is preferably rectangular but may be any shape capable of achieving resonance at the desired communication frequency. Note that other shapes may be desired to change the polarization of the antenna or to achieve polarization in more than one angle. Polarization defines the desired angle of the electric field that the antenna responds to or creates depending on whether it is receiving or transmitting. For example, the slot may have a “C” shape to achieve a desired polarization. One skilled in the art of antenna design and wireless communications system setup would readily know the desired antenna parameters (orientation, polarization, gain, bandwidth, impedance, etc.) of the antenna required to maximize communications performance for their particular system. In FIG. 3, slot 64 is coupled to circuit board 100 by a parallel transmission line, as shown in FIG. 4.

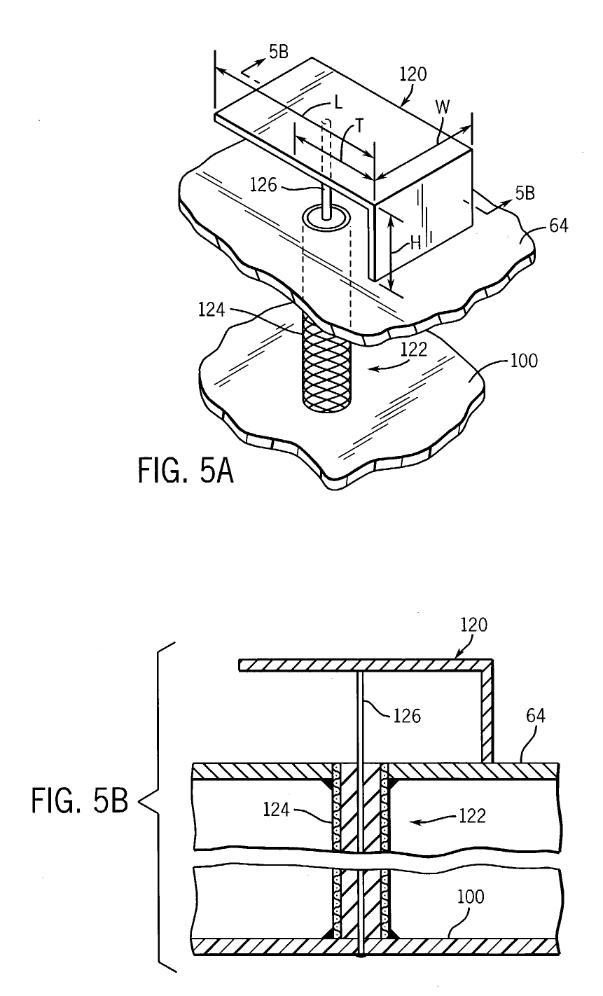

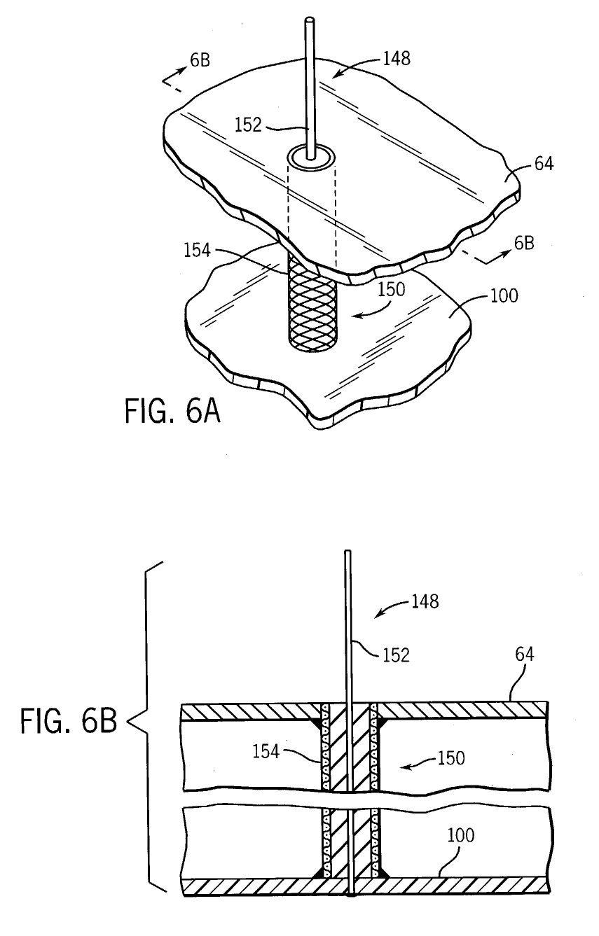

In FIG. 4, the sides or lengths 104, 106 of slot 102 are coupled to printed circuit board 100 by way of a transmission line formed of two line cables 108, 110 and impedance matching transformer 112. Cables 108, 110, by way of example, may be soldered to slot 102 and impedance transformer 112. The cables extending from impedance matching transformer 112 to board 100 may also be soldered. The cable impedance that should be matched is 300 ohms for cables 108, 110. Although impedance matching is not required to achieve functionality, it is preferred in order to maximize system performance. FIG. 4 shows the preferred coupling arrangement. However, there are many other arrangements that can achieve connection such as one or two wire coaxial cabling. (Note that different connection cables will have different impedances and matching requirements.) FIGS. 3 and 4 illustrate the preferred embodiment of the component for enabling wireless communication with network 12 (slot antenna). FIGS. 5-6 illustrate alternate embodiments (antennas) of this component.

FIGS. 5A and 5B illustrate inverted F-antenna 120 in which the center conductor of a coaxial cable 122 couples antenna 120 to circuit board 100. (The F-antenna 120 includes a top horizontal portion, a side vertical portion and a portion of the center conductor that extends above shield 64, as discussed below.) The coaxial cable 122 comprises a coaxial cable shield 124 and an inner cable center conductor 126. One end of a coaxial cable shield 124 is coupled to and around an opening in Faraday shield 64 preferably by means of a solder connection. However, coaxial cable shield 124 may be coupled using a bulkhead connector or other devices. The other end of coaxial cable shield 124 is soldered to a ground on the circuit board 100 (not shown). Inner cable center conductor 126 of the cable 122 couples the inverted F-antenna 120 to a transceiver circuit on circuit board 100. As shown in FIG. 5A, “L” is the length of antenna, “T” is the length between the closed end of the antenna and the desired location of inner cable center conductor 126, “W” is the width of the antenna and “H” is the height of the antenna. The width (W) and length (L) of the inverted F-antenna 120 dictate the frequency of transmission and reception. L is usually λ/4 of the desired frequency of operation. However, L and W are again adjusted together to achieve the required frequency of operation and bandwidth of the antenna. H is usually a small fraction of the length L. The distance T is determined by the impedance of coaxial cable 122. The desired value of T is such that the impedance of the antenna matches the impedance of coaxial cable 122. Note that the antenna impedance and coaxial cable 122 impedance do not have to match in order for the system to operate, however, the best performance is achieved when they are matched. As T is shortened the impedance of the antenna is lowered. The antenna 120 is made from a highly conductive material such as aluminum, tin or other moldable metals. Impedance matching (not shown) between cable 122 and circuit board 100 is achieved similar to the preferred embodiment.

FIGS. 6A and 6B illustrate a monopole antenna 148, another alternative embodiment of the antenna enabling component. In particular, a center conductor 152 of coaxial cable 150 couples the monopole antenna 148 to circuit board 100. Coaxial cable shield 154 has two ends, one coupled to and around an opening in Faraday shield 64, and the other end coupled to ground on circuit board 100. Coaxial cable conductor 152 has two ends, one end coupled to the transceiver circuit on circuit board 100 and the other end extending away from shield 64 to form the monopole antenna 148 (the extended portion). The extent to which the conductor 152 extends from the shield 64 dictates the frequency for communication. The frequency of operation is usually λ/4 for a monopole antenna. Impedance matching (not shown) between cable 150 and circuit board 100 is achieved similar to the preferred embodiment.

FIGS. 5-6 illustrate only two alternative embodiments. There are a variety of other antenna embodiments that can be used to enable wireless communication such as a cavity-backed slot and a slot array.

All of the antenna embodiments, including the preferred embodiment, can be placed on any exterior surface of shield 64 and at any orientation. The dimension and orientation dictate the particular frequencies and application desired.

The foregoing description of embodiments of the invention has been presented for purposes of illustration and description. It is not intended to be exhaustive or to limit the invention to the precise form disclosed and modifications and variations are possible in light of the above teachings or may be acquired from practice of the invention. The embodiment was chosen and described in order to explain the principles of the invention and its practical application to enable one skilled in the art to utilize the invention in various embodiments and with various modifications as are suited to the particular use contemplated. It is intended that the scope of the invention be defined by the claims appended hereto and their equivalents.

What is claimed is:

1. A printer adapted to print jobs from a network, the printer comprising:
a Faraday shield for covering a plurality of electrical parts in the printer, the shield including a component for enabling wireless communication with the network.

2. The printer of claim 1, wherein the component for enabling includes an antenna.

3. The printer of claim 1, wherein the component for enabling includes a slot antenna.

4. The printer of claim 1, wherein the component for enabling includes a monopole antenna.

5. The printer of claim 1, wherein the component for enabling includes an inverted F-antenna.

6. The printer of claim 1, wherein the Faraday shield is metal.

7. The printer of claim 1, wherein the Faraday shield encloses the electrical parts.

8. The printer of claim 1, wherein the plurality of electrical parts are installed on a printed circuit board.

9. A printer adapted to print jobs from a network via a wireless connection, the printer comprising:
a controlling component for controlling the operation of the printer, the controlling component including a plurality of electrical parts; and
a shield for enclosing the controlling component, the shield being constructed to (1) reduce electromagnetic radiation generated by the plurality of electrical parts from escaping the printer and (2) reducing stray electromagnetic radiation from affecting the plurality of electrical parts of the controlling component,
the shield including a component for enabling wireless communication with the network.

10. The printer of claim 9, wherein the component for enabling includes an antenna.

11. The printer of claim 9, wherein the component for enabling includes a slot antenna.

12. The printer of claim 9, wherein the component for enabling includes a monopole antenna.

13. The printer of claim 9, wherein the component for enabling includes an inverted F-antenna.

14. The printer of claim 9, wherein the shield is a metal Faraday shield.

15. A printer adapted to achieve wireless communication with a network, the printer comprising:
a Faraday shield for enclosing a plurality of electrical parts in a printer, the shield including an antenna coupled to at least one of the plurality of electrical parts for communicating with the network.

16. The printer of claim 15, wherein the antenna is a slot antenna.

17. The printer of claim 15, wherein the antenna is a monopole antenna.

18. The printer of claim 15, wherein the antenna is an inverted F-antenna.

19. The printer of claim 15, wherein the Faraday shield is metal.
